(19) United States
(12) Patent Application Publication
(10) Pub. No.: US 2016/0369392 A1
(43) Pub. Date: Dec. 22, 2016

(54) MASK FRAME ASSEMBLY AND METHOD OF MANUFACTURING THE SAME

(71) Applicant: Samsung Display Co., Ltd., Yongin-si (KR)

(72) Inventor: Minseok KIM, Yongin-si (KR)

(21) Appl. No.: 14/949,160

(22) Filed: Nov. 23, 2015

(30) Foreign Application Priority Data
Jun. 19, 2015 (KR) 10-2015-0087285

(51) Int. Cl. C23C 16/04; B23K 11/11

(52) U.S. Cl. CPC C23C 16/042; B23K 11/11

(57) ABSTRACT

A mask frame assembly including a frame including an opening, blocking members welded to a first side of the frame including through holes at locations corresponding to the opening, and mask members welded to a second side spaced apart from the first side of the frame. The mask members include pattern holes at locations corresponding to the opening.

### CROSS-REFERENCE TO RELATED APPLICATION

This application claims priority from and the benefit of Korean Patent Application No. 10-2015-0087285, filed on Jun. 19, 2015, which is hereby incorporated by reference for all purposes as if fully set forth herein.

### BACKGROUND

Field

Exemplary embodiments relate to a mask frame assembly for depositing a thin film. More particularly exemplary embodiments relate to a mask frame assembly that uses a split mask and a method of manufacturing the same.

Discussion of the Background

An organic light-emitting diode (OLED) display apparatus has wide viewing angles, high contrast, and fast response times. Thin film layers of the OLED display apparatus, such as an emissive layer, may be formed through a deposition process using a mask frame assembly.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments include a mask frame assembly and a method of manufacturing the same.

Additional aspects will be set forth in part in the detailed description which follows, and, in part, will be apparent from the disclosure, or may be learned by practice of the inventive concept.

An exemplary embodiment discloses a mask frame assembly including a frame including an opening, blocking members welded to a first side of the frame including through holes at locations corresponding to the opening, and mask members welded to a second side spaced apart from the first side of the frame. The mask members include pattern holes at locations corresponding to the opening.

An exemplary embodiment also discloses a method of manufacturing a mask frame assembly. The method includes preparing a frame with an opening, welding blocking members including through holes to a first side of the frame such that the through holes correspond to the opening, and welding mask members including pattern holes to a second side spaced of the frame such that the pattern holes correspond to the opening.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a diagram illustrating a deposition process using a mask frame assembly according to an exemplary embodiment.

FIG. 2 is an exploded perspective view of the mask frame assembly of FIG. 1.

FIG. 3 is a plan view of the mask frame assembly of FIG. 2.

FIGS. 4A, 4B, 4C, and 4D are sequential plan views of a process of manufacturing the mask frame assembly of FIG. 3.

FIG. 5 is a cross-sectional view of an exemplary OLED display device that may be manufactured through the deposition process of FIG. 1.

### DETAILED DESCRIPTION

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. As such, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

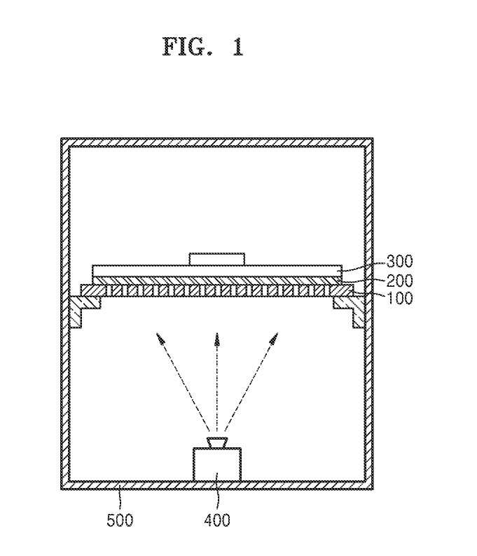

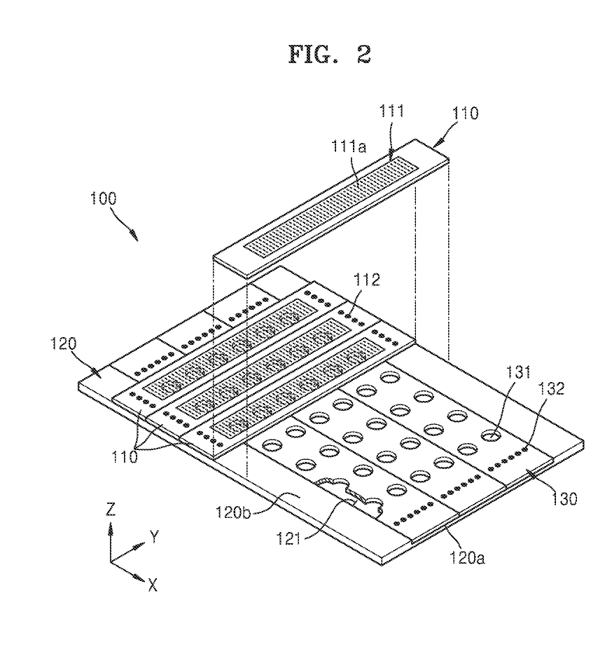

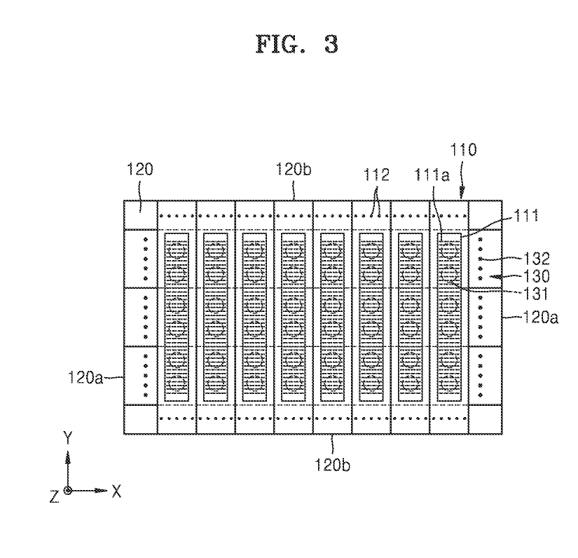

FIG. 1 is a diagram for describing a deposition process by installing a mask frame assembly 100 in a deposition chamber 500. FIGS. 2 and 3 illustrate a mask frame assembly 100 according to an exemplary embodiment.

As shown in FIGS. 2 and 3, the mask frame assembly 100 of an exemplary embodiment includes a frame 120 having an opening 121, blocking members 130, and mask members 110. The blocking members 130 may have distal ends that are fixed to a first side 120a. The mask members 110 may have distal ends that are fixed to a second side 120b.

Although several mask members 110 are illustrated in FIG. 2 in order to show the opening 121 and the blocking member 130 for convenience of description, the mask members 110 may completely cover the blocking members 130 inside the opening 121, as shown in FIG. 3, after completely being manufactured.

The frame 120 may form an outside frame of the mask frame assembly 100 and may have a rectangular shape having the opening 121 in the center of the frame 120.

Both ends of the blocking members 130 may be fixed to the first side 120a of the frame 120 by spot welding. Both ends of the mask members 110 may be fixed to the second side 120b through spot welding. The second side 120b may be substantially perpendicular to and connected to the first side 120a. Reference numeral 132 denotes welding portions of the blocking members 130. Reference numeral 112 denotes welding portions of the mask members 110.

As seen in the figures, the welding portions 132 of the blocking members 130 and the welding portions 112 of the mask members 110 may be formed at locations that do not interfere with each other. In other words, the blocking members 130 may be welded to the first side 120a of the frame 120 in a first direction X across the opening 121 of the frame 120. The mask members 110 may be welded to the second side 120b of the frame 120 in a second direction Y that is substantially perpendicular to the first direction X across the opening 121 of the frame 120. Thus, no interference occurs due to the welding portions 112 and 132. This will be described in detail later in connection with a manufacturing process.

The blocking members 130 may be elongated members and may include circular through holes 131. The elongated blocking members 130 may be adjacent to each other and installed in the frame 120 to fill the opening 121 of the frame 120.

The mask members 110 may also be elongated members and may include a pattern holes 111a located in the opening 121. A pattern region 111, in which the pattern holes 111a are formed, may not be circular like the through holes 131 but may be continuously formed in the second direction Y across the opening 121. Thus, a region of the pattern region 111, in which the pattern holes 111a and the through holes 131 overlap each other, may be a deposition pattern. In other words, deposition gas of a deposition source 400 of FIG. 1 may only pass through a region in which the pattern region 111 and the through holes 131 overlap each other. A remaining region (i.e., a region where the pattern region 111 and the through holes 131 do not overlap each other) may be blocked by the blocking members 130. Thus, the overlapping region may be the deposition pattern, and a thin film layer corresponding to the deposition pattern may be formed on a deposition target 200 of FIG. 1.

The mask members 110 and the blocking members 130 may include nickel, nickel alloy, nickel-cobalt alloy, etc.

As shown in FIG. 1, if the mask frame assembly 100 having the structure described above is installed in a deposition chamber 500 to perform the deposition process, the deposition gas generated by the deposition source 400 may pass through the overlapping region between the pattern region 111 of the mask members 110 and the through holes 131 of the blocking members 130 and may be deposited on the deposition target 200 to form a thin film layer. Reference numeral 300 denotes a magnet applying a magnetic force to allow the mask frame assembly 100 to be adhered to the deposition target 200.

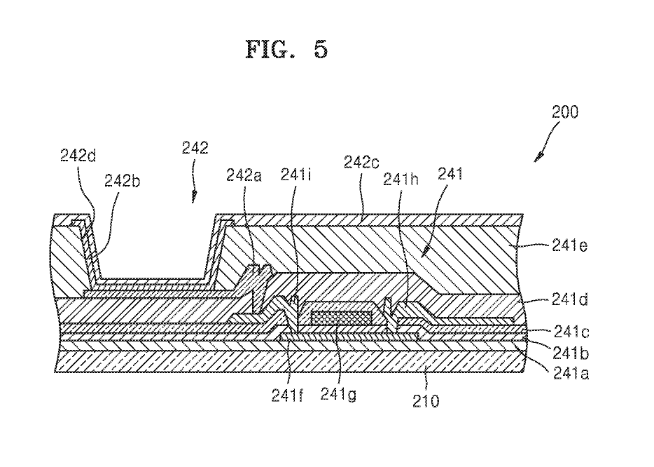

Meanwhile, the deposition target 200 may be, for example, a substrate 210 of an OLED display apparatus of FIG. 5. A cross-sectional structure of the OLED display apparatus including the substrate 210 will now be briefly described.

Referring to FIG. 5, a thin film transistor 241 and an electroluminescence (EL) device 242 are provided on the substrate 210. In more detail, an active layer 241f may be formed on a buffer layer 241a provided on the substrate 210. The active layer 241f may have a source and drain region doped with N or P type impurities at high concentration. The active layer 241f may include an oxide semiconductor. For example, the oxide semiconductor may include an oxide of a material selected from Group 4, 12, 13, or 14 metal elements such as zinc (Zn), indium (In), gallium (Ga), tin (Sn), cadmium (Cd), germanium (Ge), and hafnium (Hf), and any combination thereof. For example, the active layer 241f may include G-I-Z-O [(In₂O₃)ₐ(Ga₂O₃)_{b}(ZnO)_{c}], wherein a, b, and c are real numbers that respectively satisfy a≧0, b≧0, and c>0. A gate electrode 241g may be formed on the active layer 241f with a gate insulating film 241b interposed therebetween. A source electrode 241h and a drain electrode 241i may be formed on the gate electrode 241g. An interlayer insulation film 241c may be provided between the gate electrode 241g and the source electrode 241h and the drain electrode 241i. A passivation film 241d may be interposed between the source electrode 241h and the drain electrode 241i and an anode electrode 242a of the EL device 242.

An insulating planarization film 241e may include acryl or the like on the anode electrode 242a. An opening 242d may be formed in the insulating planarization film 241e, and then, the EL device 242 may be formed.

The EL device 242 may display image information by emitting red, green, and blue light according to the applied current. The EL device 242 may include the anode electrode 242a connected to the drain electrode 241i of the thin film transistor 241. The EL device 242 may receive a positive power voltage from the drain electrode 241i. The EL device 242 may include a cathode electrode 242c formed to cover the entire pixel. The EL device 242 may receive a negative power voltage from the cathode electrode 242c. The EL device 242 may include an emission layer 242b disposed between the anode electrode 242a and the cathode electrode 242c to emit light.

A hole injection layer (HIL), a hole transport layer (HTL), an electron transport layer (ETL), an electron injection layer (EIL), and the like may be stacked adjacent to the emission layer 242b.

For reference, the emission layer 242b may be separately formed on each pixel so that pixels emitting red, green, and blue light constitute a unit pixel. Alternatively, the emission layer 242b may be commonly formed over the entire pixel area regardless of locations of the pixels. In this regard, the emission layer 242b may be formed by vertically stacking or combining layers including light-emission materials that emit, for example, red light, green light, and blue light. Combinations of other colors may also be possible as long as white light may be emitted. A color converting layer or a color filter that converts the white light into a light of a predetermined color may be further provided.

The emission layer 242b is very vulnerable to moisture, and thus, for example, a thin film encapsulation layer (not shown), in which an organic film and an inorganic film are alternately stacked, may be formed on the cathode electrode 242c to protect the emission layer 242b.

The emission layer 242b of the OLED display apparatus may be formed, for example, through a deposition process using the mask frame assembly 100.

The mask frame assembly 100 may be formed through a manufacturing process below.

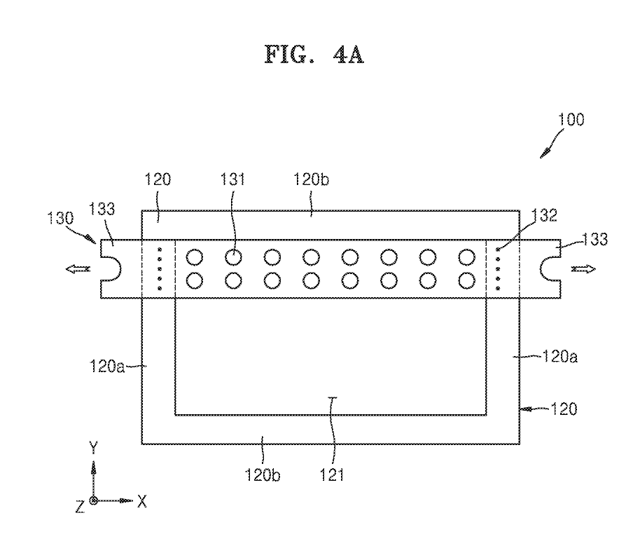

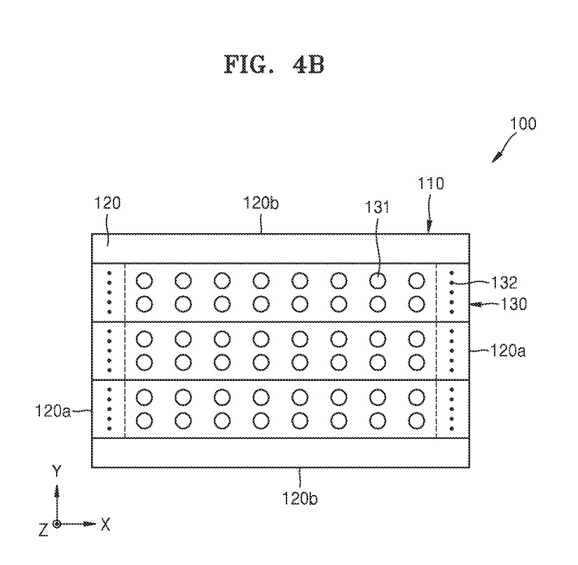

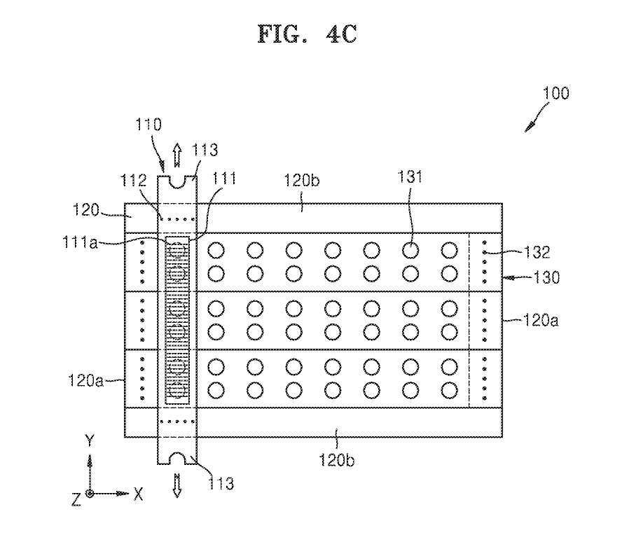

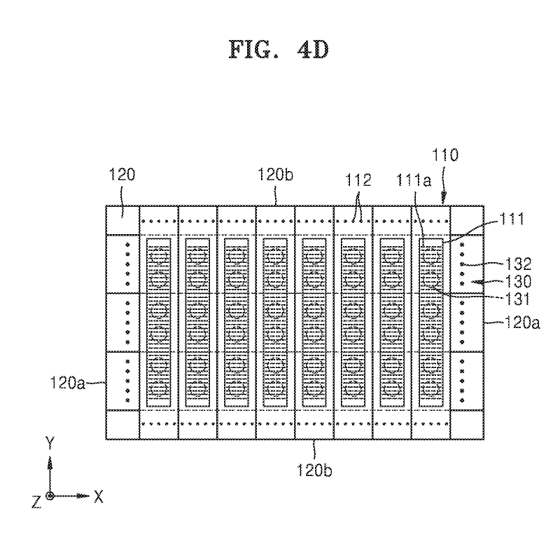

As shown in FIG. 4A, the frame 120 may have a rectangular frame shape having the opening 121 in the center of the rectangular frame. The frame 120 may be prepared. The blocking members 130 may be welded on the frame 120 one-by-one. Both ends 133 of each of the blocking members 130 may be spot welded to the first side 120a of the frame 120 after being tightly pulled and elongated in the first direction X. After completing welding and forming the welding portions 132, both ends 133 of the blocking members 130 protruding from the frame 120 may be cut off. These protruding portions are extra portions prepared from an elongation process and may be cut off and removed after welding is complete.

Such a process may be repeated to make the blocking members 130 adjacent to each other such that the opening 121 of the frame 120 may be filled as shown in FIG. 4B.

If the blocking members 130 are completely installed, the mask members 110 may be installed as shown in FIG. 4C.

Both ends 113 of each of the mask members 110 may be spot welded to the second side 120b of the frame 120 after being tightly pulled and elongated in the second direction Y. If welding is complete and the welding portions 112 are formed, both ends 113 of the mask members 110 protruding from the frame 120 may be cut off. These protruding portions are extra portions prepared from an elongation process and may be cut off and removed after welding is complete.

However, as seen here, the welding portions 132 of the blocking members 130 and the welding portions 112 of the mask members 110 are formed at locations that do not interfere with each other. Thus, a separate additional operation for processing the welding portions 112 and 132 is unnecessary.

In other words, if the welding portions 132 of the blocking members 130 are formed at locations that interfere with the mask members 110, an operation of polishing and planarizing the welding portions 132 needs to be performed. If not, a firm coupling structure between the mask members 110 and the frame 120 may not be formed due to the welding portions 132.

However, because the welding portions 132 of the blocking members 130 and the welding portions 112 of the mask members 110 are formed at locations that do not interfere with each other, the problem described above is prevented and a separate additional operation for processing the welding portions 112 and 132 is unnecessary, and thus the manufacturing process may be simplified.

If the mask members 110 are installed to be adjacent to each other by repeating a welding process of the mask members 110 in order to completely fill the opening 121 of the frame 120, the mask frame assembly 100 may be completely manufactured as shown in FIG. 4D.

Therefore, the mask frame assembly 100 having the above-described structure and the manufacturing method may be used to prevent interference due to the welding portions 112 and 132 when the blocking members 130 and the mask members 110 are welded to the frame 120. Thus, an inconvenient operation of polishing the protruding welding portions 112 and 132 is unnecessary, thereby simplifying the manufacturing process and accordingly, significantly increasing productivity.

The mask members 110 and the blocking members 130 are formed as split elongated members, which reduces a self-weight, compared to a structure in which the mask members 110 and the blocking members 130 are formed as one plate, thereby preventing a droop phenomenon due to the self-weight.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. A mask frame assembly, comprising:
a frame comprising an opening;
blocking members welded to a first side of the frame comprising through holes at locations corresponding to the opening; and
mask members welded to a second side spaced apart from the first side of the frame, the mask members comprising pattern holes at locations corresponding to the opening.

2. The mask frame assembly of claim 1, wherein:
the frame comprises a rectangular shape having the opening in a center of the frame, and
the first side and the second side are connected to each other in a perpendicular direction.

3. The mask frame assembly of claim 1, wherein:
the blocking members are welded to the first side in a first direction across the opening, and
the mask members are welded to the second side in a second direction substantially s perpendicular to the first direction across the opening.

4. The mask frame assembly of claim 1, wherein:
the through holes are circular, and
a region in which the pattern holes are present is non-circular.

5. The mask frame assembly of claim 1, wherein an area comprising a region of pattern holes is larger than an area comprising the through holes.

6. The mask frame assembly of claim 5, wherein deposition patterns correspond to the overlapping of the pattern holes and the through holes.

7. The mask frame assembly of claim 1, wherein the blocking members comprise five elongated members that are adjacent to each other and are welded side-by-side to the first side.

8. The mask frame assembly of claim 1, wherein the mask members comprise five elongated members that are adjacent to each other and are welded side-by-side to the second side.

9. The mask frame assembly of claim 1, wherein the blocking members are located between the frame and the mask members.

10. A method of manufacturing a mask frame assembly, the method comprising:
preparing a frame with an opening;
welding blocking members comprising through holes to a first side of the frame such that the through holes correspond to the opening; and
welding mask members comprising pattern holes to a second side spaced of the frame such that the pattern holes correspond to the opening.

11. The method of claim 10, wherein welding the blocking members further comprises:
pulling and elongating both ends of the blocking members in a first direction;
welding and fixing the blocking members to the first side; and
cutting off an extra portion of both ends of the blocking members protruding from the frame.

12. The method of claim 11, wherein welding the mask members further comprises:
pulling and elongating both ends of the mask members in a second direction different from the first direction;
welding and fixing the mask members to the second side; and
cutting off an extra portion of both ends of the mask members protruding from the frame.

13. The method of claim 12, wherein:
the frame comprises a rectangular shape having the opening in a center of the frame, and
the first side and the second side of the frame are connected to each other in a perpendicular direction.

14. The method of claim 13, wherein:
the blocking members are welded to the first side in the first direction across the opening, and
the mask members are welded to the second side in the second direction perpendicular to the first direction across the opening.

15. The method of claim 10, wherein:
the through holes are circular, and
a region in which the pattern holes are present is non-circular.

16. The method of claim 10, wherein an area comprising the pattern holes is larger than an area comprising the through holes.

17. The method of claim 16, wherein deposition patterns correspond to the overlapping of the pattern holes and the through holes.

18. The method of claim 10, wherein the blocking members comprise five elongated members that are adjacent to each other and are welded side-by-side to the first side.

19. The method of claim 10, wherein the mask members comprise five elongated members that are adjacent to each other and are welded side-by-side to the second side.

20. The method of claim 10, wherein the blocking members are located between the frame and the mask members.
